(19) United States
(12) Patent Application Publication
(10) Pub. No.: US 2010/0282504 A1
(43) Pub. Date: Nov. 11, 2010

(54) HIGH IMPEDANCE TRACE

(75) Inventors: Simon CHANG, Taipei City (TW); Patrik LUNDELL, Svedala (SE); Bernie WANG, Taipei County (TW); Adam Lin, Taipei County (TW); Jungle Chu, Taipei City (TW); Howard Zen Chang, Taipei (TW); Lucas Chuang, Yilan County (TW)

Correspondence Address: HARRITY & HARRITY, LLP, 11350 RANDOM HILLS ROAD, SUITE 600, FAIRFAX, VA, 22030, US

(73) Assignee: Sony Ericsson Mobile Communications AB, Lund (SE)

(21) Appl. No.: 12/437,648

(22) Filed: May 8, 2009

(51) Int. Cl. H05K 1/02; H05K 3/10

(52) U.S. Cl. 174/268; 29/846

(57) ABSTRACT

A microwave conducting structure is described, in which a first electrically conductive layer, a first dielectric substrate with a first dielectric constant being arranged on the first electrically conductive layer, and at least one electrically conductive trace with a first width being arranged on or within the dielectric substrate are provided. A track of a second dielectric substrate having a second width being wider than the first width and a second dielectric constant being lower than the first dielectric constant, is arranged locally between the first dielectric substrate and the conductive trace so as to extend along the conductive trace such that the conductive trace operates electrically as being arranged on the second dielectric substrate.

### TECHNICAL FIELD

The present invention generally relates to substrates with electrically conductive structures being impedance matched for high frequency signals and a method for producing such structures.

### BACKGROUND OF THE INVENTION

Electrically conductive structures may be formed of electrically conductive traces produced on or within a substrate so as to form conductive paths between various electrical components, e.g., semiconductors and/or other components being arranged on and/or in the substrate. Such traces are typically made of copper or some other electrically conductive material that need not have ideal conducting properties and thus less conductive than copper. The substrate on which the traces are produced may, for example, be a printed circuit board (PCB) or some other suitable material upon which electrically conductive traces can be produced.

Producing thin conductive traces on a substrate may present a number of design challenges, particularly with respect to sensitive, high impedance traces. High impedance traces are commonly used, for example, for matching the trace impedance to the input impedance of an electric circuit, e.g., such as a low noise amplifier (LNA) or similar circuitry. Typically, the input impedance for an LNA is from between about 100 to about 150 ohm. For such dimensions, the corresponding copper trace width may be from between about 3 to about 4 mil, if applied on and/or in a PCB, using a standard FR4 structure. The LNA is used herein as an example, and the associated input impedance for other electric circuits may be as low as less than about 50 ohm or less, or as high as up to about 200 ohm, or more. The trace width may be adapted accordingly, to be about 5 mil or less, or about 10 mil or more.

The etching process can easily have about 1 mil tolerance. The offset could therefore be as high as 25%, for example, with respect to a 4 mil trace. This relatively large variation may limit the control of the impedance matching accuracy and thus the sensitivity of the LNA may be adversely affected.

Accordingly, it would be beneficial to use a technique to eliminate or at least mitigate the offset variations in the etching process, so as to improve the yield rate.

### SUMMARY OF THE INVENTION

One aspect of the invention may eliminate or at least minimize the offset variations in the etching process or other formation process used to produce an electrically conductive trace to effect a superior yield rate.

To compensate for the variation from the etching process or other formation process, increasing the trace width may prove to be desirable. By only replacing the material underneath an electrically conductive trace with low dielectric material, the trace width could be increased artificially. With this invention, e.g. implemented during the PCB process, the trace width could be pre-enlarged to compensate for the imprecise etching control and thus improve the yield rate.

At least some of the above-identified advantages may be achieved according to a first embodiment of the invention, in which a microwave conducting structure includes a first electrically conductive layer, a first dielectric substrate with a first dielectric constant being arranged on the first electrically conductive layer, and at least one electrically conductive trace with a first width being arranged on or within the dielectric substrate. A track of a second dielectric substrate, having a second width being wider than the first width and a second dielectric constant being lower than the first dielectric constant, may be arranged locally between the first dielectric substrate and the conductive trace, so as to extend along the conductive trace such that the conductive trace operates electrically as being arranged on the second dielectric substrate.

This should i.a. be interpreted such that the track of the second dielectric substrate may extend along the conductive trace in a manner allowing a second dielectric constant Eᵣ to be safely used for calculating a characteristic impedance Z₀ of the microwave conducting structure, e.g., in a variable Eᵣ of expressions 1, 2a, 3 given below for calculating characteristic impedance Z₀ of the microwave conducting structure, for example, a microstrip strip structure or a stripline structure.

A second embodiment of the invention, may include the features of the first embodiment, and be directed to a microwave conducting structure in which the second dielectric substrate may extend substantially centrally along the electrically conductive trace.

A third embodiment of the invention, may include the features of the first embodiment, and be directed to a microwave conducting structure in which the electrically conductive trace may extend adjacent to the second dielectric substrate.

A fourth embodiment of the invention, may include the features of the first embodiment, and be directed to a microwave conducting structure in which the microwave conducting structure may be a microstrip structure.

A fifth embodiment of the invention, may include the features of the first embodiment, and be directed to a microwave conducting structure in which the microwave conducting structure may be a stripline structure.

A sixth embodiment of the invention, may include the features of the first embodiment, and be directed to a microwave conducting structure in which the microwave conducting structure may have a high characteristic impedance Z₀ that is above 50 or above 100 ohm.

A seventh embodiment of the invention, may include the features of the first embodiment, and be directed to a microwave conducting structure in which the second width may be less than about ten times the first width.

An eighth embodiment of the invention, may include the features of the first embodiment or the seventh embodiment, and be directed to a microwave conducting structure in which the first width of the electrically conductive trace may be narrower than about 5 or about 10 mil.

A ninth embodiment of the invention may be directed to a substrate structure including a first microwave conducting structure and a second microwave conducting structure of the same kind both according to any one of the preceding embodiments, in which the first microwave conducting structure and the second microwave conducting structure may be arranged so as to form a balanced microwave conducting structure.

The expression “the same kind” should be interpreted such that both microwave conducting structures are of the same preceding embodiment. However, this should not be interpreted such that the two microwave conducting structures are identical, since there may indeed be small variations within one and the same embodiment, for example, due to fabrication tolerances. A balanced microwave structure may be produced, for example, by arranging the first microwave conducting structure and the second microwave conducting structure substantially in parallel to each other.

A tenth embodiment of the invention may be directed to a communication device including an antenna arrangement, an electric circuit, and a microwave conducting structure according to any one of the preceding first to eighth embodiments, in which the microwave conducting structure may connect the antenna arrangement to the electric circuit.

In addition, at least one of the above-identified advantages may be achieved according to an eleventh embodiment of the invention, which may provide a method for producing a microwave structure. The method may include the steps of: providing a substrate structure with at least a first electrically conductive layer and a dielectric layer including a first material with a first higher dielectric constant, where the conductive layer may extend under and substantially in parallel with the dielectric layer; and the steps of forming at least one groove in the dielectric layer exposing the first conductive layer; and the steps of arranging a dielectric material with a second lower dielectric constant in the groove so as to form a dielectric track with a first width; and the steps of forming at least one electrically conductive trace on and above and along the dielectric track.

A twelfth embodiment of the invention, may include the features of the eleventh embodiment, and be directed to a method in which the at least one groove may be formed by the steps of: arranging a mask pattern on the dielectric layer so as to create at least one track of exposed dielectric layer; and the steps of removing the exposed parts of the dielectric layer so as to form at least one groove in the dielectric layer exposing the first conductive layer.

A thirteenth embodiment of the invention, may include the features of the eleventh embodiment, and be directed to a method in which the dielectric material with a second lower dielectric constant may be arranged in the groove by the steps of: arranging the dielectric material on top of the dielectric layer and in the groove; and the steps of removing the dielectric material from the dielectric layer by a planarization process.

A fourteenth embodiment of the invention, may include the features of the eleventh embodiment, and be directed to a method in which the conductive trace may be formed by the steps of: arranging a second electrically conductive layer on the dielectric layer and on the dielectric track; and the steps of arranging a mask track so as to leave a unexposed part of the second electrically conductive layer above and along the dielectric track, which mask track may have a second width that is narrower than the first width of the dielectric track; and the steps of removing exposed parts of the second conductive layer so as to form at least one electrically conductive trace on and above and along the dielectric track.

A fifteenth embodiment of the invention, may include the features of the eleventh embodiment, and be directed to a method in which the conductive trace, the dielectric track, and the dielectric layer is covered by a solder mask.

It should be emphasized that the terms “comprises/comprising” “includes/including,” and their variants, when used in this specification should be taken to specify the presence of stated features, integers, steps or components, but does not preclude the presence or addition of one or more other features, integers, steps, components or groups thereof.

Similarly, the steps in the methods described herein must not necessarily be executed in the order in which they appear and other embodiments of the methods may comprise more ore less steps without falling outside the scope of the present invention.

### BRIEF DESCRIPTION OF THE DRAWINGS

The present invention will now be described in more detail in relation to the enclosed drawings, in which:

FIG. 1a shows a communication device in the form of a cell phone 10,

FIG. 1b shows the rear of the communication device of FIG. 1a,

FIG. 2a is a schematic illustration of a typical microstrip structure 20a viewed from a short end along a surface copper trace 22a,

FIG. 2b is a schematic illustration of a typical microstrip structure 20b viewed from a short end along an embedded copper trace 22b,

FIG. 2c is a schematic illustration of a typical stripline structure 20c viewed from a short end along an embedded copper trace 22c,

FIG. 2d is a schematic illustration of an embodiment of the present invention forming a microstrip structure 20d viewed from a short end along an electrically conductive trace 22d,

FIG. 2d′ is a schematic illustration of the embodiment in FIG. 2d viewed from above,

FIG. 2e is a schematic illustration of an embodiment of the present invention forming a stripline structure 20e viewed from a short end along an electrically conductive trace 22e,

FIG. 3 is a schematic illustration of an exemplifying standard six layer PCB arrangement 30,

FIG. 4a is a schematic illustration of the PCB arrangement 30, at least partly without layer L31,

FIG. 4b is a schematic illustration of the PCB arrangement 30 in FIG. 4a provided with a photoresist pattern,

FIG. 4b′ is a schematic top view of the PCB arrangement 30 in FIG. 4b,

FIG. 4c is a schematic illustration of the PCB arrangement 30 with groove LE1, LE2 of the conductive layer L32 exposed,

FIG. 4c′ is a schematic top view of the PCB arrangement 30 in FIG. 4c,

FIG. 4d is a schematic illustration of the PCB arrangement 30 in FIGS. 4c-4c′ with the photoresist pattern removed,

FIG. 4d′ is a schematic top view of the PCB arrangement 30 in FIG. 4d,

FIG. 4e is a schematic illustration of the PCB arrangement 30 in FIGS. 4d-4d′ with a dielectric material DM deposited on top of the PCB arrangement 30,

FIG. 4f is a schematic illustration of the PCB arrangement 30 in FIG. 4e with the deposited material DM removed from the top of the PCB arrangement 30,

FIG. 4f′ is a schematic top view of the PCB arrangement 30 in FIG. 4f,

FIG. 4g is a schematic illustration of the PCB arrangement 30 in FIGS. 4f-4f′ with an electrically conductive layer L31 deposited on top of the PCB arrangement 30,

FIG. 4h is a schematic illustration of the PCB arrangement 30 in FIG. 4g with a photoresist pattern PRT1, PRT2 provided on top of layer 31,

FIG. 4h′ is a schematic top view of the PCB arrangement 30 in FIG. 4h,

FIG. 4i is a schematic illustration of the PCB arrangement 30 in FIGS. 4h-4h′ with parts of the electrically conductive layer 31 removed,

FIG. 4i′ is a schematic top view of the PCB arrangement 30 in FIG. 4i,

FIG. 4j is a schematic illustration of the PCB arrangement 30 in FIGS. 4i-4i′ with the photoresist pattern PRT1, PRT2 removed,

FIG. 4j′ is a schematic top view of the PCB arrangement 30 in FIG. 4j′,

FIG. 4k is a schematic illustration of the PCB arrangement 30 in FIGS. 4j-4j′ with a solder mask S40 deposited on top of the PCB arrangement 30, and

FIG. 5 is a flowchart illustrating a method according to an embodiment of the present invention.

### DETAILED DESCRIPTION OF PREFERRED EMBODIMENTS

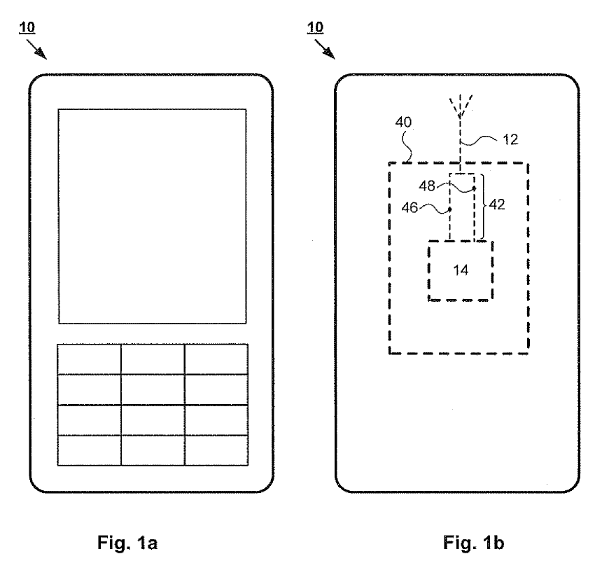

FIG. 1a is a schematic illustration of a communication device in the form of a cell phone 10. However, the invention is not limited to cell phones. On the contrary, the invention may be implemented in any suitable communication device, for example, any suitable receiver or transceiver arrangement or other device.

FIG. 1b shows cell phone 10 from a rear perspective. The phantom lines in FIG. 1b are intended to schematically illustrate that exemplifying cell phone 10 comprises an antenna arrangement 12, a trace structure 42, an electric circuit 14 and a substrate arrangement 40. Antenna arrangement 12 may be arranged to operatively receive wireless transmissions, for example, radio transmissions and/or other electromagnetic transmissions. Trace structure 42 may be arranged to operatively connect antenna arrangement 12 to electric circuit 14. Trace structure 42 may be arranged on and/or within substrate arrangement 40, so as to form an electrically conductive structure arranged to operatively conduct microwaves or other media. Also, antenna arrangement 12 and/or electric circuit 14 may be arranged in and/or on substrate arrangement 40. It should be emphasized that cell phone 10 is merely an example of a communication device in which an antenna arrangement, a trace structure, an electrical circuit and a substrate arrangement according to an embodiment of the invention may be implemented.

In FIG. 1b, it is assumed that trace structure 42 is a differential trace structure with a first electrical conductive path 46 and a second electrical conductive path 48. First and second paths 46, 48 may be substantially identical.

It is further assumed that electric circuit 14 is a differential circuit such, as a differential low noise amplifier (LNA) that may be operatively connected to antenna arrangement 12, for example, via differential trace structure 42.

It should be emphasized that other embodiments of the invention may use trace structure 42 with a single electrically conductive path 46 or 48, for example, for other non-differential electrical circuits. In fact, the invention can be applied to substantially all single-ended traces, differential traces or multi-trace configurations. Substrate arrangement 40 may include, for example, an insulating dielectric or some other suitable material on and/or within which electrically conductive paths 46, 48 are produced. For printed circuit boards (PCBs), for example, various dielectric materials can be used to provide different insulating values based on operating characteristics and/or design considerations. A few examples of possible dielectric materials include polytetrafluoroethylene, FR-1, FR-2, FR-4 (where FR is an acronym for Flame Retardant) or CEM-1, CEM-2, CEM-3 (where CEM is an acronym for Composite Epoxy Material), and the like. However, the invention is not limited to PCBs or to the aforementioned dielectric materials. Paths 46, 48 may, for example, be made from copper or some other electrically conducting material, including materials being less conductive than copper such for paths 46, 48.

Conductive path 46 or 48 may include, for example, a microstrip structure or a stripline structure.

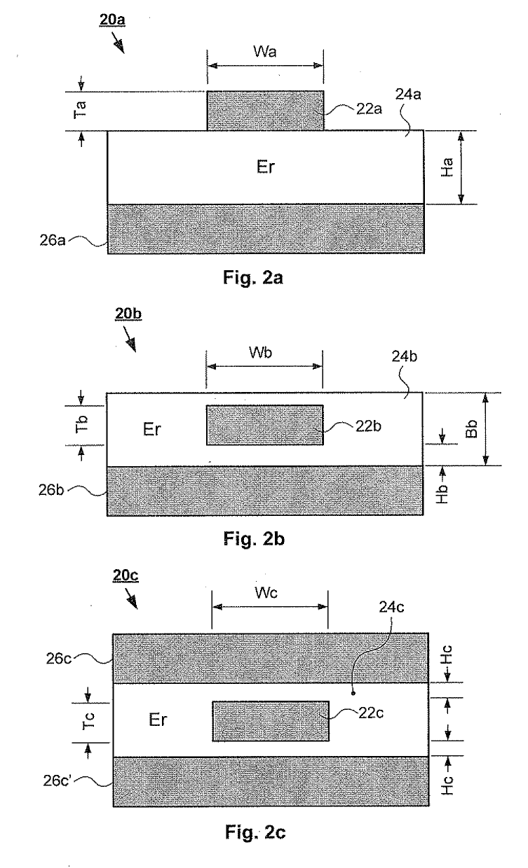

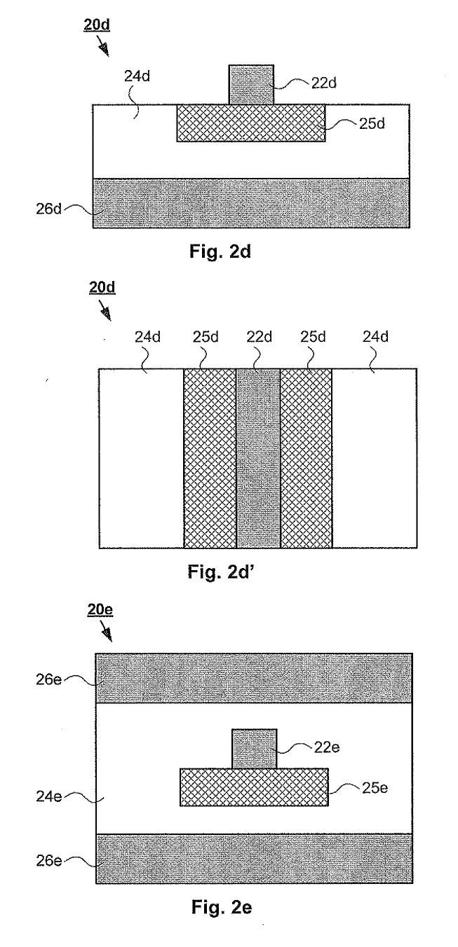

FIG. 2a is a schematic illustration of an exemplary microstrip structure 20a, including a surface copper trace 22a, a dielectric substrate 24a, and a reference ground plane 26a, for example, made of copper.

The characteristic impedance of the microstrip 20a can be, for example approximated by the expression:

$${Z}_{0 a} = [ \frac{87}{\sqrt{{E}_{r} + 1 , 414}} ] ln ( \frac{5 , 89 {H}_{a}}{0 , 8 {W}_{a} + {T}_{a}} ) \qquad ( 1 )$$

where Eᵣ is the dielectric constant of substrate 24a;
Hₐ is the height of substrate 24a;
Tₐ is the thickness of trace 22a; and
Wₐ is the width of trace 22a.

FIG. 2b is a schematic illustration of a typical microstrip structure 20b, including an embedded copper trace 22b, a dielectric substrate 24b, and a reference ground plane 26b, for example, made of copper.

The characteristic impedance of microstrip structure 20b can be approximated by the expressions:

$$\begin{matrix}{Z}_{0 b} = [ \frac{87}{\sqrt{{E}_{r}^{′} + 1 , 414}} ] ln ( \frac{5 , 89 {H}_{b}}{0 , 8 {W}_{b} + {T}_{b}} ) & ( 2 a ) \\ {E}_{r}^{′} = {E}_{r} [ 1 - e ( \frac{- 1 , 55 {B}_{b}}{{H}_{b}} ) ] & ( 2 b )\end{matrix}$$

where Eᵣ is the dielectric constant of substrate 24b;
H_{b} is the height of substrate 24b;
T_{b} is the thickness of trace 22b; and
W_{b} is the width of the 22b.

FIG. 2c is a schematic illustration of an exemplary stripline structure 20c, including a copper trace 22c embedded in a substrate 24c and interposed between a first ground plane 26c and a second ground plane 26c′, both made, for example, of copper.

The characteristic impedance of stripline structure 20c can be approximated by the expression:

$${Z}_{0 c} = [ \frac{60}{\sqrt{{E}_{r}}} ] ln ( \frac{1 , 9 ( 2 {H}_{c} + {T}_{c} )}{0 , 8 {W}_{c} + {T}_{c}} ) \qquad ( 3 )$$

or by the expression:

$${Z}_{0 c} = [ \frac{60}{\sqrt{{E}_{r}}} ] ln ( \frac{4 {H}_{c}}{0 , 67 π {W}_{c} ( 0 , 8 + \frac{{T}_{c}}{{W}_{c}} )} ) \qquad ( {3}^{′} )$$

where Eᵣ is the dielectric constant of substrate 24c;
H_{c} is the distance between trace 22c and upper ground plane 26c and lower ground plane 26c′;
T_{c} is the thickness of trace 22c; and
W_{c} is the width of trace 22c.

The expressions 1, 2a, 3 and 3′ demonstrate that an increase in trace width Wₐ, W_{b}, or W_{c} may cause the logarithmic factor of the expression to decrease, which can be compensated by decreasing the dielectric constant Eᵣ causing an increase of the left ratio factor of the expressions.

Thus, if the trace width Wₐ, W_{b}, W_{c} is increased and the dielectric constant Eᵣ is decreased correspondingly, it is possible to maintain characteristic impedance Z₀ at the same level.

Since the trace width Wₐ, W_{b}, W_{c} is increased it follows that possible offset variations in the etching process will have less effect on the characteristic impedance Z_{0.} This may improve the control of the impedance matching and the yield rate, which is in line with at least one of the aspects of the invention set forth above in the Summary.

However, generally decreasing the dielectric constant Eᵣ of substrate 24a, 24b, 24c in its entirety to compensate for an increase of trace width Wₐ, W_{b}, W_{c} necessitates a corresponding width increase of all other traces occurring in and/or on substrate 24a, 24b, 24c. Otherwise, characteristic impedance may not be maintained. However, generally increasing the trace width for all conductive traces on and/or in a substrate may not be desirable, since the physical space may a scarce resource in the modern, highly-packed substrates of today.

Instead, according to an embodiment of the present invention, the dielectric constant is only decreased locally under those thin traces that are actually sensitive to variations in the etching process, for example, high impedance traces that are used for matching the trace impedance to the high input impedance of am LNA or other high impedance electric circuit.

FIG. 2d shows a schematic illustration of an embodiment of the present invention in the form of a microstrip structure 20d. However, other embodiments of the invention may use other structures for conducting electromagnetic waves, such as microwaves or other electromagnetic waves. Microstrip structure 20d, in FIG. 2d, may include an electrically conductive trace 22d, a reference ground plane 26d, a first dielectric substrate 24d with a first higher dielectric constant, and a track 25d of a second dielectric substrate with a second lower dielectric constant. The track of second dielectric substrate 25d may extend locally between first dielectric substrate 24d and conductive trace 22d, and adjacent to and along conductive trace 22d.

The expression “locally” means that the thickness and particularly the width of track 25d are dimensioned such that trace 22d may operatively function as being arranged on second dielectric substrate 25d with the second lower dielectric constant. In other words, the thickness and particularly the width of track 25d may be dimensioned such that characteristic impedance Z₀ of trace 22d can be determined by letting Eᵣ be the second lower dielectric constant in expression (1) above. “Locally” is in contrast to “globally,” where globally would imply that substantially first dielectric substrate 24d would be entirely covered by second dielectric substrate 25d.

The width of track 25d may be, for example, less than about 2 times, or about 4 times, or about 6 times, or about 10 times, or about 15 times, or about 20 times, or about 50 times, or less than about 100 times the width of trace 22d. Naturally, the actual dimensions depend on the structure and the trace width, etc.

First dielectric substrate 24d may be made, for example, from FR4 (Eᵣ≈4,3) and second dielectric substrate 25d may be made, for example, from Polyimide (Eᵣ≈3,5) or Epoxy Resin (Eᵣ≈3,4) or Lucite (Eᵣ≈2,5) or Polycarbonate (Eᵣ≈2,9) or Polyethylene (Eᵣ≈2,5) or Silicone (Eᵣ≈3,9) or Teflon (Eᵣ≈2,1).

FIG. 2d′ shows a schematic illustration of the embodiment in FIG. 2d in a plan view.

FIG. 2e illustrates another embodiment of the present invention in the form of a stripline structure 20e. Stripline structure 20e in FIG. 2e may include an electrically conductive trace 22e, a lower ground plane 26d, a first dielectric substrate 24e with a first dielectric constant, and a track of a second dielectric substrate 25e with a second lower dielectric constant, and a second upper ground plane 27e. The track of second dielectric substrate 25e may extend locally between first dielectric substrate 24e and conductive trace 22e, and adjacent to and along conductive trace 22e.

The expression “locally” means that the thickness and particularly the width of track 25d is dimensioned such that characteristic impedance Z₀ of trace 22e can be determined by letting Eᵣ be the second lower dielectric constant in expression (3) or (3′) above. “Locally” is in contrast to “globally,” where globally would imply that second dielectric substrate 25e may extend within first dielectric substrate 24e substantially in its entirety.

The width of track 25e may be, for example, less than about 2 times, or about 4 times, or about 6 times, or about 10 times, or about 15 times, or about 20 times, or about 50 times, or less than about 100 times the width of the trace 22e. Naturally, the actual dimensions depend on the structure and the trace width, etc.

First dielectric substrate 24e may be made, for example, from FR4 (Eᵣ≈4,3) and second dielectric substrate 25e may be made, for example, from Polyimide (Eᵣ≈3,5) or Epoxy Resin (Eᵣ≈3,4) or Lucite (Eᵣ≈2,5) or Polycarbonate (Eᵣ≈2,9) or Polyethylene (Eᵣ≈2,5) or Silicone (Eᵣ≈3,9) or Teflon (Eᵣ≈2,1).

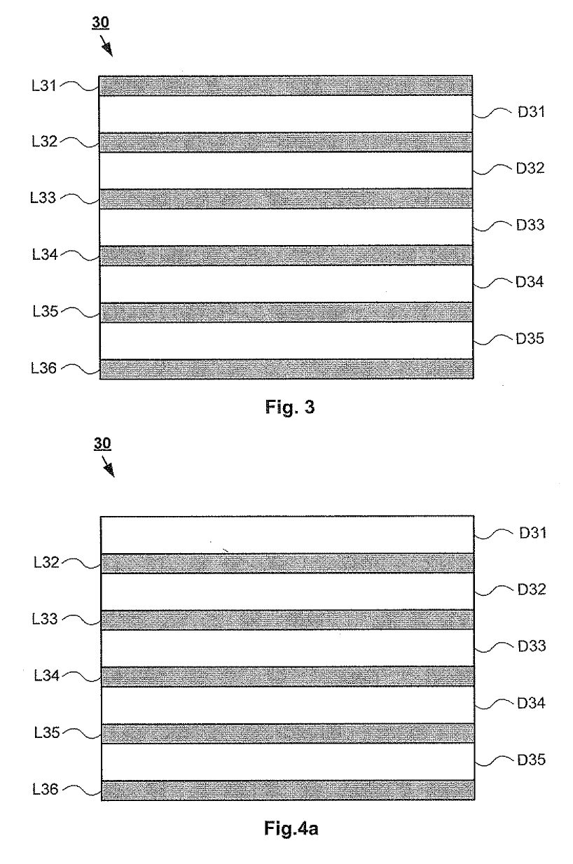

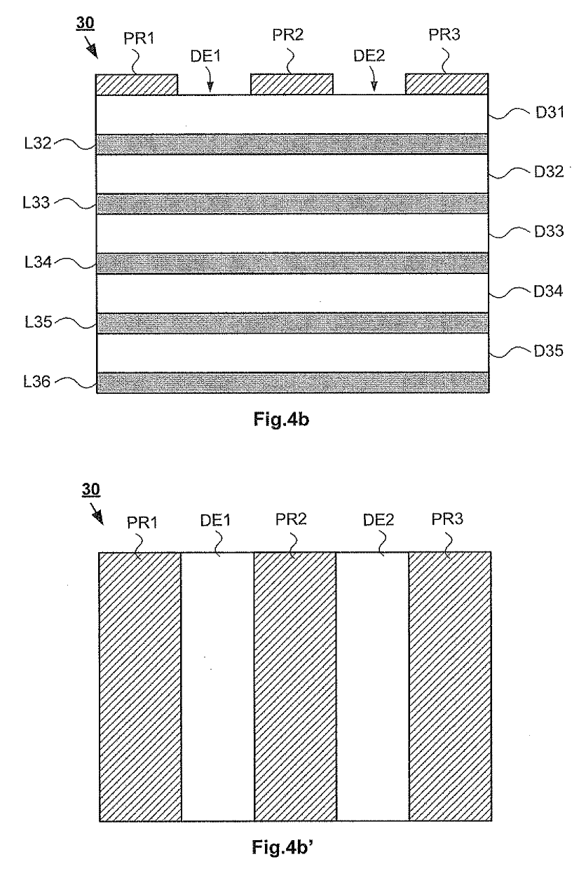

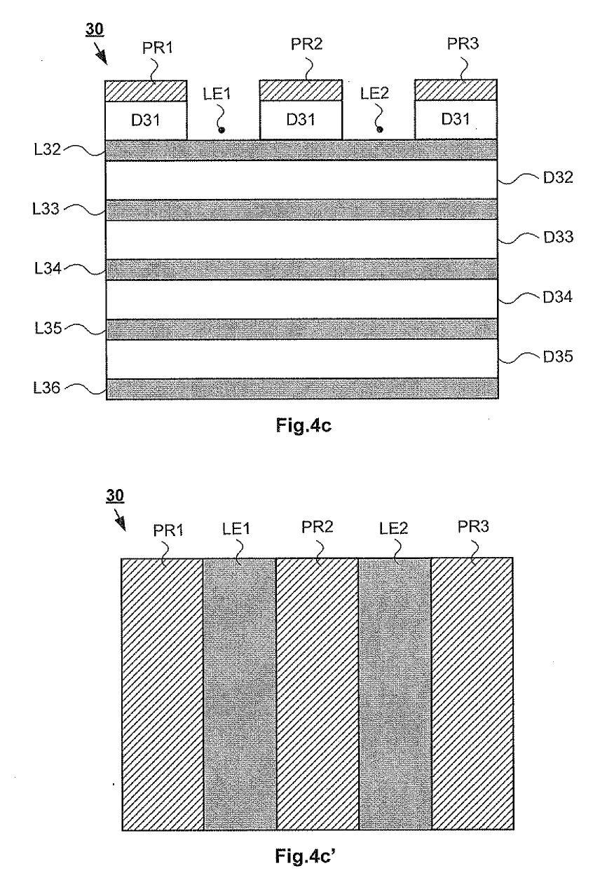

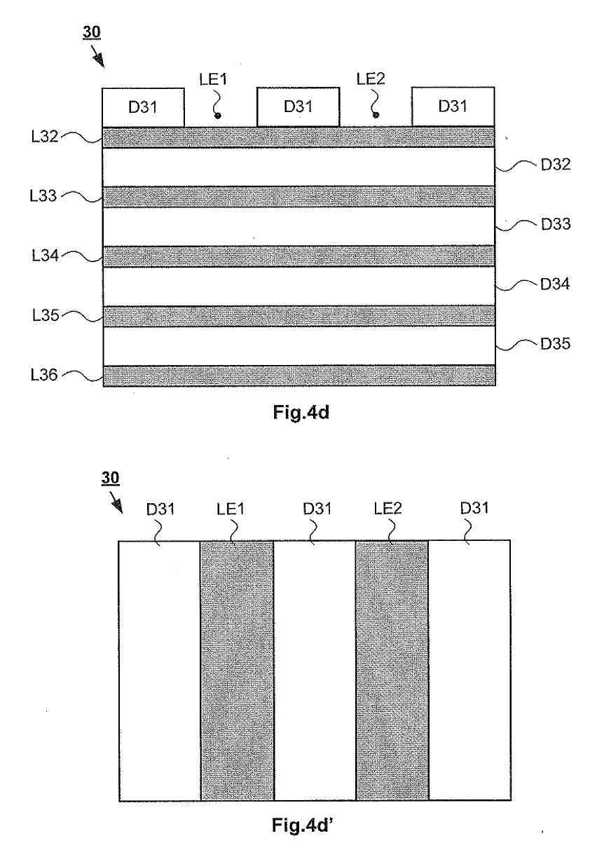

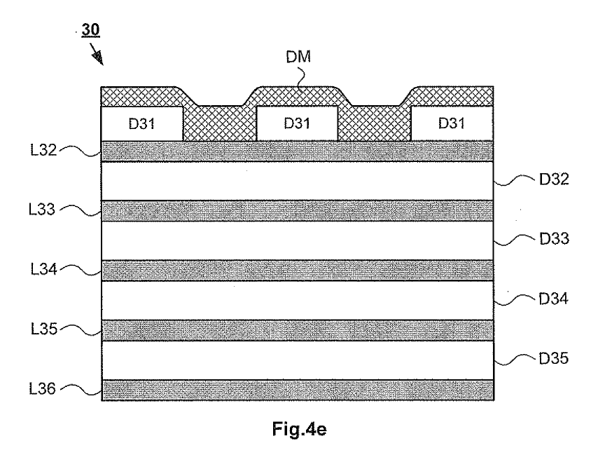

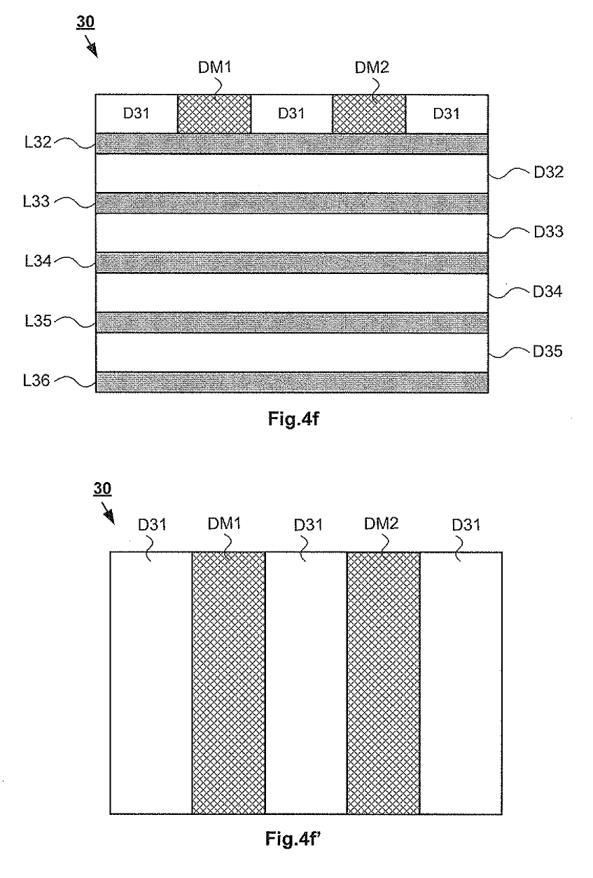

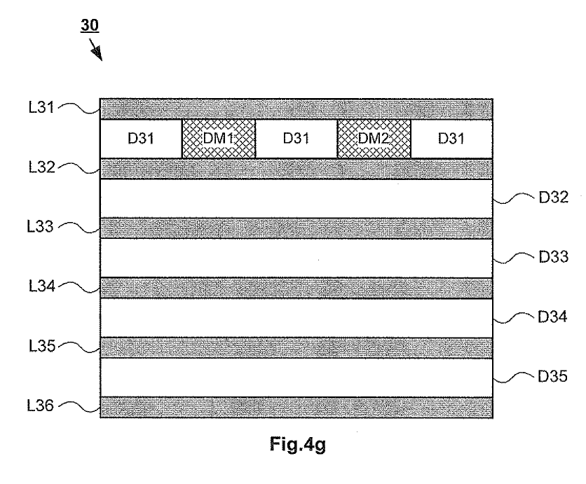

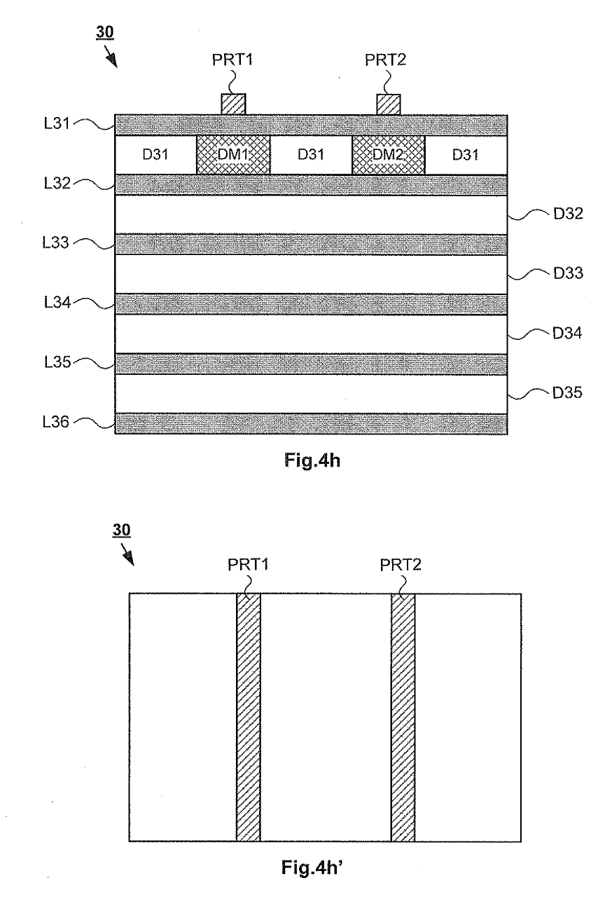

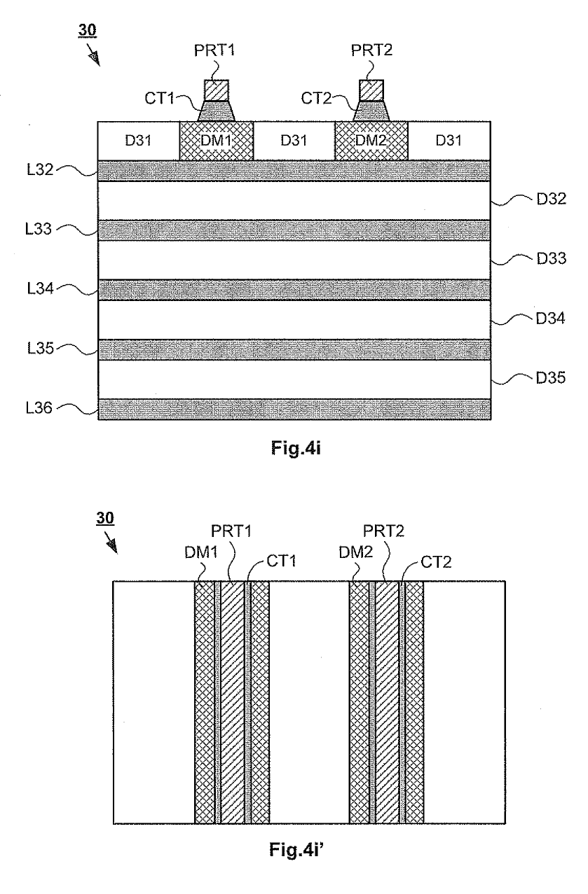

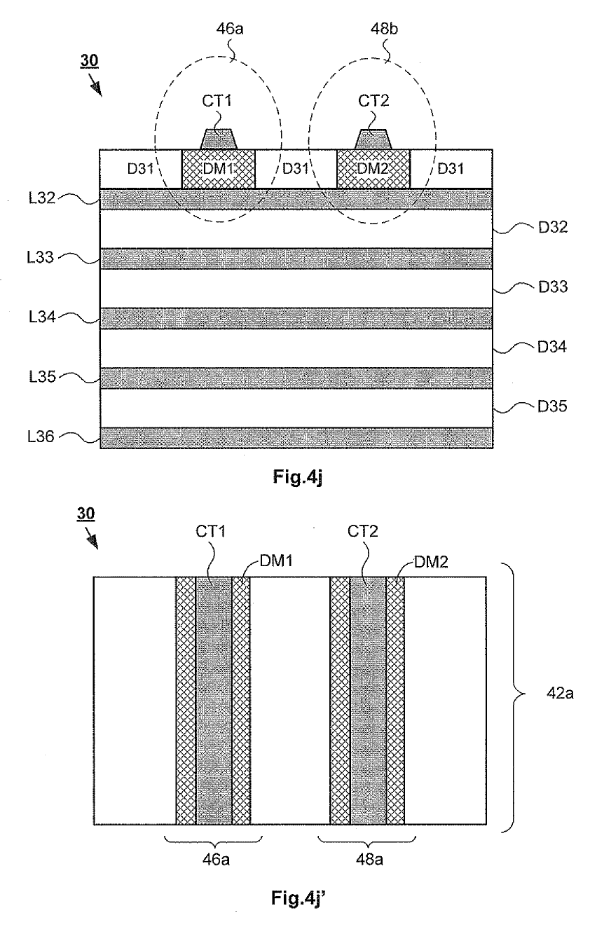

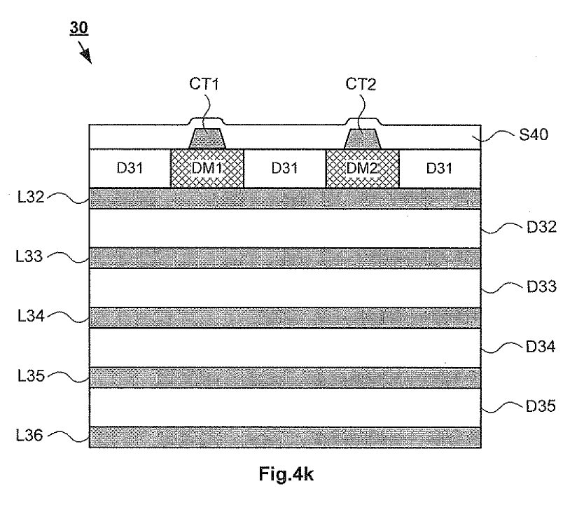

Now, a method for producing a structure that conducts electromagnetic waves according to an embodiment of the invention will be described with reference to FIG. 3 and FIGS. 4a-5. The structure in FIGS. 4a-4k is, in essence, a microstrip structure. However, the method is applicable mutatis mutandis to other embodiments of the invention, for example, to a stripline structure or any other substrate structure arranged to operatively conduct microwaves or other waveforms.

FIG. 3 shows a schematic illustration of an exemplifying six layer PCB arrangement 30. A wide range of layered PCBs may be used and need no detailed description as such. However, six layered PCB arrangement 30 in FIG. 3 will be used for describing the method mentioned above and some basic features will therefore be mentioned.

In FIG. 3, layers L31 to L36 may include thin layers of copper or some other electrically conductive material for use in connection with layered PCBs. Conductive layers L31 to L36 may have a thickness, for example, that is less than about 1 mil, or less than about 1.5 mil, or less than about 2 mil, or less than about 3 mil. Layers D31 to D35 may be, for example, thin layers of dielectric material, such as FR4 or some other dielectric material used in connection with layered PCBs. Generally, dielectric layers D31 to D35 may have a thickness, for example, that is less than about 2 mil, or less than about 3 mil, or less than about 4 mil. However, select ones of layers D31 to D35 (e.g. some of the inner layers such as layer D33) may have a thickness, for example, of less than about 15 mil or less than about 20 mil, or less than about 25 mil.

The electrically conductive layers that may be used, for example, include:
L31 signals
L32 ground (GND)
L33 signals
L34 signals or ground (GND)
L35 power (VCC)
L36 signals

FIG. 4a shows a schematic illustration of the PCB arrangement 30 in FIG. 3, after stacking up layers L32 to L36 and layers D31 to D35.

FIG. 4b shows that a pattern of photoresist has been arranged on top of layer D31 in PCB arrangement 30 (see the line-shadowed areas in FIG. 4b). The photoresist material may be, for example, PolyMethylMethAcrylate (PMMA), PolyMetylGlutarimide (PMGI), or any other suitable photoresist used in connection with PCBs. The photoresist pattern may be arranged by any suitable method, e.g., deposition.

FIG. 4b′ shows a plan view of PCB arrangement 30 in FIG. 4b. As can be seen in FIG. 4b′, the photoresist pattern forms three substantially parallel tracks PR1, PR2, and PR3. Tracks PR1 and PR3 may be arranged in a substantially symmetrical manner, on each side of track PR2, so as to expose two substantially parallel tracks DE1, DE2 of dielectric layer D31 of PCB arrangement 30.

FIG. 4c shows PCB arrangement 30 with tracks DE1, DE2 of exposed dielectric layer D31 removed, so as to expose underlying electrically conductive layer L32 of PCB arrangement 30. Removal of these parts of dielectric layer D31 may be achieved by means of an etching process or another removal technique.

FIG. 4c′ shows a plan view of PCB arrangement 30 in FIG. 4c. As can be seen in FIG. 4c′, the exposed parts of conductive layer L32 may form two substantially parallel grooves LE1 and LE2. The observant reader realizes that grooves LE1, LE2 correspond in length-extension and width-extension to tracks DE1, DE2, respectively. As indicated above, grooves LE1, LE2 may be formed by any suitable method, e.g. etching.

FIG. 4d is a schematic illustration of PCB arrangement 30 in FIGS. 4c-4c′ with photoresist patterns PR1, PR2, PR3 removed. The photoresist can be removed by means of any suitable removal process, e.g. a chemical process.

FIG. 4d′ shows a plan view of PCB arrangement 30 in FIG. 4d.

FIG. 4e is a schematic illustration of PCB arrangement 30 in FIGS. 4d-4d′, wherein a second dielectric material DM has been arranged at least in grooves LE1, LE2 of PCB arrangement 30 (see the web-shadowed parts in FIG. 4e). For example, dielectric material DM may be arranged on top of dielectric layer D31 of PCB arrangement 30. Here, it is assumed that the dielectric constant of the dielectric material in layer D31 is higher than the dielectric constant of dielectric material DM. Dielectric material DM may be arranged by any suitable method, e.g. by deposition.

FIG. 4f is a schematic illustration of PCB arrangement 30 in FIGS. 4d-4d′, where the deposited dielectric material DM has been removed from the surface of layer D31 of PCB arrangement 30, by means of a chemical mechanical planarization (CMP) process or any other planarization process or similar planning technique. The planarization process may leave the surface of PCB arrangement 30 in a substantially flat or planar condition. The removal process may leaves the deposited material in grooves LE1, LE2, so as to form two new tracks DM1, DM2 of dielectric material DM. The observant reader realizes that tracks DM1, DM2 correspond in length-extension and width-extension to grooves LE1, LE2, respectively.

FIG. 4f′ shows a plan view of PCB arrangement 30 in FIG. 4f.

FIG. 4g shows PCB arrangement 30 in FIGS. 4f-4f, provided with a further electrically conductive layer L31, for example, made of copper or other conductor, arranged on top of layer D31 and on top of tracks DM1, DM2 of PCB arrangement 30. Further conductive layer L31 may be arranged by any suitable method, e.g. deposition.

FIG. 4h shows PCB arrangement 30 in FIG. 4g provided with a photoresist pattern arranged on top of layer L31 in PCB arrangement 30 (see the line-shadowed areas in FIG. 4h). The photoresist pattern may include a first photoresist track PRT1 and a second photoresist track PRT2, each being arranged along and at or near a center of tracks DM1 and DM2, respectively. The tracks of photoresist pattern PRT1, PRT2 may be arranged by any suitable method, e.g. by deposition.

According to the above, tracks PRT1, PRT2 correspond in length-extension to tracks DM1, DM2, respectively. However, the width of tracks PRT1, PRT2 may be considerably less than the width of tracks DM1, DM2, respectively. The width of photoresist tracks PRT1, PRT2 may be chosen such that suitable electrically conductive tracks CT1, CT2 can be produced (e.g., by means of etching) upon tracks DM1, DM2, as will be explained in more detail later. The trace width of electrically conductive tracks CT1, CT2 may be less than around 5 mil or at least less than around 10 mil, e.g., from about 3˜4 mil. The width of tracks DM1, DM2 may be, for example, at least 3 times, or at least 5 times, or at least 10 times, or at least 20 times, or at least 50 times, or at least 100 times the width of tracks PRT1, PRT2, respectively.

FIG. 4h′ shows a plan view of PCB arrangement 30 in FIG. 4h.

FIG. 4i shows PCB arrangement 30 with the electrically conductive layer L31 removed to the extent that is was not covered by photoresist tracks PRT1, PRT2.

Removal of the electrically conductive layer L31 may be accomplished by means of an etching process or other removal technique.

FIG. 4i′ shows a plan view of PCB arrangement 30 in FIG. 4h.

As can be seen in FIGS. 4i-4i′, the removal of layer L31 may leave a first electrically conductive track CT1 and a second conductive track CT2 formed by the remaining parts of electrically conductive layer L31. Note that tracks CT1, CT2 have been illustrated with oblique sides to show that a certain amount of under-etch may occur when etching tracks as thin as tracks CT1 and CT2.

FIG. 4j is a schematic illustration of PCB arrangement 30 in FIGS. 4i-4i′ with photoresist pattern PRT1, PRT2 having been removed by means of any suitable removal process, e.g. a chemical process.

FIG. 4j′ shows a plan view of PCB arrangement 30 in FIG. 4j.

A person skilled in the art studying FIGS. 2d-2d′ and FIGS. 4j-4j′ realizes that conductive trace CT1, dielectric layer DM1, and conductive layer L32 (for example, being a ground reference as discussed above in connection with FIG. 3) may form a first microstrip structure 46a. Similarly, conductive trace CT1, dielectric layer DM2, and conductive layer L32 may form a second microstrip structure 48a. In fact, microstrip structures 46a, 48a can be used as a differential trace structure 42a for a differential electric circuit forming an embodiment of differential trace structure 42 that was discussed above with reference to FIG. 1b. However, the fact that the differential embodiment in FIGS. 4j-4j′ is based on a microstrip structure or similar type of structure does not limit the invention to microstrip structures or preclude use of other differential embodiments of the invention, e.g., stripline structures or similar types of structures.

By arranging tracks DM1, DM2 with low dielectric constant locally under thin traces CT1, CT2, being sensitive to variations in the etching process, it will be possible to increase the width of traces CT1, CT2, and thereby eliminate or at least mitigate the offset variations in the etching process, so as to improve the yield rate.

FIG. 4k is a schematic illustration of PCB arrangement 30 in FIGS. 4j-4j′, where a solder mask S40 has been deposited on top of dielectric layer D31, local dielectric tracks DM1, DM2, and two electrically conductive tracks CT1, CT2. Solder mask S40 may be any solder mask suitable in connection with a PCB arrangement.

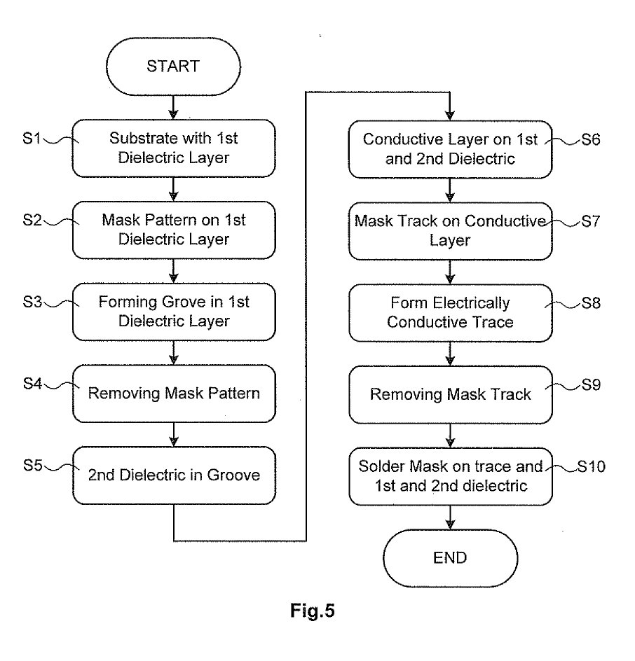

FIG. 5 is a flowchart illustrating a method for producing a microwave structure according to an embodiment of the present invention.

In a first step S1, a substrate structure 30 is provided with at least a first electrically conductive layer L32 and a dielectric layer D31 including a first material with a first higher dielectric constant. Conductive layer L32 may extend globally under and substantially in parallel with dielectric layer D31.

In a second step S2, a mask pattern, e.g., a photoresist pattern PR1, PR2, PR3 may be arranged on dielectric layer D31, so as to create at least one exposed track DE1, DE2 of dielectric layer D31, by any suitable method, e.g. by deposition.

In a third step S3, exposed parts of dielectric layer D31 may be removed, so as to form at least one groove LE1, LE2 in dielectric layer D31 leaving parts of conductive layer L32 exposed. Grooves LE1, LE2 may be formed by any suitable method, e.g., by etching.

In a fifth step S5, mask patterns PR1, PR2, PR3 may be at least partially removed from the remaining parts of dielectric layer D31, for example, by means of any suitable removal process, e.g. a chemical process.

In a sixth step S6 a dielectric material DM with a second lower dielectric constant may be arranged in grooves LE1, LE2 so as to form a dielectric tracks DM1, DM2, for example, by first depositing dielectric material DM on layer D31 and in grooves LE1, LE2, and then removing second dielectric material DM from the surface of layer D31. Dielectric material DM may be arranged by any suitable method, e.g., by deposition. Dielectric material DM can be removed, for example, by means of a chemical mechanical planarization (CMP) process or any other planarization process.

In a seventh step S7, a second electrically conductive layer L31 is arranged on dielectric layer D31 and on dielectric tracks DM1, DM2. Conductive layer L31 may be arranged by any suitable method, e.g. by deposition.

In an eighth step S8, at least one of mask tracks PRT1, PRT2 may be arranged on second conductive layer L31 above and along dielectric tracks DM1, DM2, which mask track PRT1, PRT2 may have a width that is less than the width of dielectric tracks DM1, DM2. Mask tracks PRT1, PRT2 may be arranged by any suitable method, e.g., by a type of deposition and/or another technique.

In a ninth step S9, uncovered parts of second conductive layer L31 may be removed so as to form at least one electrically conductive traces CT1, CT2 on dielectric tracks DM1, DM2. Removal of the uncovered parts of second electrically conductive layer L31 may be achieved, for example, by means of etching or another removal technique.

In a tenth step S10, mask tracks PRT1, PRT2 may be substantially removed, for example, using any suitable removal process, e.g., a chemical process.

It should be understood that the present invention is not limited to the embodiments described and illustrated herein; rather, the skilled person will recognize that many changes and modifications may be made within the scope of the appended claims.

For example, PCB arrangement 30 may be any other suitable substrate arrangement or other support on and/or within which a structure according to the present invention may be arranged or formed.

Similarly, one or several electrically conductive traces CT1, CT2 may be arranged on a single dielectric track DM1, DM2 made of dielectric material DM having a second lower dielectric constant. Naturally, the width of dielectric track DM1, DM2 may be concomitantly increased, for example, up to doubled in case of two conductive traces, or up to tripled in case of three conductive traces, and so on, i.e., the track width for one trace times the corresponding number of traces used.

What is claimed is:

1. A microwave conducting structure comprising:
a first electrically conductive layer;
a first dielectric substrate, having a first dielectric constant, disposed on the first electrically conductive layer; and
at least one electrically conductive trace, of a first width, disposed on and/or within the dielectric substrate, where:
a track of a second dielectric substrate, having a second width being wider than the first width and a second dielectric constant being lower than the first dielectric constant, is arranged locally, between the first dielectric substrate and the conductive trace, to extend along the conductive trace such that the conductive trace operates electrically as being arranged on the second dielectric substrate.

2. The microwave conducting structure of claim 1, where the second dielectric substrate extends substantially centrally along the electrically conductive trace.

3. The microwave conducting structure of claim 1, where the electrically conductive trace extends adjacent to the second dielectric substrate.

4. The microwave conducting structure of claim 1, where the microwave conducting structure is a microstrip structure.

5. The microwave conducting structure of claim 1, where the microwave conducting structure is a stripline structure.

6. The microwave conducting structure of claim 1, where the microwave conducting structure has characteristic impedance (Z₀) of at least 50 ohm.

7. The microwave conducting structure of claim 1, where the second width is less than ten times the first width.

8. The microwave conducting structure of claim 1, where the first width of is less than about 5 mil.

9. The microwave conducting structure of claim 1, where the microwave conducting structure comprises a substrate.

10. A communication device comprising:
an antenna arrangement;
an electric circuit; and
a microwave conducting structure including:
a first electrically conductive layer;
a first dielectric substrate, having a first dielectric constant, disposed on the first electrically conductive layer; and
at least one electrically conductive trace, of a first width, disposed on and/or within the dielectric substrate, where:
a track of a second dielectric substrate, having a second width being wider than the first width and a second dielectric constant being lower than the first dielectric constant, is arranged locally, between the first dielectric substrate and the conductive trace, to extend along the conductive trace such that the conductive trace operates electrically as being arranged on the second dielectric substrate, and the microwave conducting structure connects the antenna arrangement to the electric circuit.

11. A method for producing a microwave structure, the method comprising:
providing a substrate structure with at least a first electrically conductive layer and a dielectric layer including a first material with a first higher dielectric constant, where the conductive layer extend under and substantially in parallel with the dielectric layer;
forming at least one groove in the dielectric layer exposing the first conductive layer;
providing a dielectric material with a second lower dielectric constant in the groove to form a dielectric track with a first width; and
forming at least one electrically conductive trace on and above and along the dielectric track.

12. The method of claim 11, where the at least one groove is formed by:
arranging a mask pattern on the dielectric layer so as to create at least one track of exposed dielectric layer; and
removing the exposed parts of the dielectric layer to form at least one groove in the dielectric layer exposing the first conductive layer.

13. The method of claim 11, wherein the dielectric material with a second lower dielectric constant is arranged in the groove by:
arranging the dielectric material on top of the dielectric layer and in the groove; and
removing the dielectric material from the dielectric layer by a planarization process.

14. The method of claim 11, where the conductive trace is formed by:
arranging a second electrically conductive layer on the dielectric layer and on the dielectric track;
arranging a mask track so as to leave a unexposed part of the second electrically conductive layer above and along the dielectric track, which mask track has a second width that is narrower than said first width of the dielectric track; and
removing exposed parts of the second conductive layer so as to form at least one electrically conductive trace on and above and along the dielectric track.

15. The method according to claim 11, where the conductive trace, the dielectric track, and the dielectric layer are covered by a solder mask.
